(19) United States
(12) Patent Application Publication
(10) Pub. No.: US 2007/0148892 A1
(43) Pub. Date: Jun. 28, 2007

(54) SEMICONDUCTOR DEVICE AND METHOD OF MANUFACTURING THE SAME

(75) Inventors: Seiji Otake, Saitama (JP); Ryo Kanda, Gunma (JP); Shuichi Kikuchi, Gunma (JP)

Correspondence Address: FISH & RICHARDSON P.C., P.O. BOX 1022, MINNEAPOLIS, MN, 55440-1022, US

(73) Assignee: Sanyo Electric Co., Ltd.

(21) Appl. No.: 11/614,527

(22) Filed: Dec. 21, 2006

(30) Foreign Application Priority Data
Dec. 27, 2005 (JP) P2005-376554

(51) Int. Cl. H01L 21/331

(52) U.S. Cl. 438/365; 438/377; 438/374

(57) ABSTRACT

In a semiconductor device of the present invention, an N type epitaxial layer is stacked on a P type single crystal silicon substrate. In the epitaxial layer, an N type diffusion layer as a base draw-out region, P type diffusion layers as an emitter region, and P type diffusion layers as a collector region are formed. The emitter region has a region having a larger diffusion width in a portion deeper than in a vicinity of a surface thereof. In a lateral PNP transistor, a smallest base width is formed in a deep portion of the epitaxial layer. By use of this structure, even in a case where the collector region is narrowed, a desired hfe value can be realized. Thus, the device size can be reduced.

### BACKGROUND OF THE INVENTION

Priority is claimed to Japanese Patent Application Number JP2005-376554 filed on Dec. 27, 2005, the disclosures of which are incorporated herein by reference in its entirety.

1. Field of the Invention

The present invention relates to a semiconductor device which realizes reduction in a device size, and a method of manufacturing the same.

2. Description of the Prior Art

As an embodiment of a conventional semiconductor device, the following lateral PNP transistor has been known. Specifically, an epitaxial layer is formed on a P type silicon substrate. An N type buried diffusion layer is formed in the silicon substrate and the epitaxial layer. In the epitaxial layer, a P type emitter diffusion layer, a P type collector diffusion layer so as to surround the emitter diffusion layer, and an N type base contact diffusion layer are formed. Thus, the lateral PNP transistor is configured. The epitaxial layer positioned between the emitter diffusion layer and the collector diffusion layer is used as a base region. Free carriers (positive holes), which are injected into the base region from the emitter diffusion layer, take a path near a surface of the epitaxial layer. This technology is described for instance in Japanese Patent Application Publication No. 2004-95781 (Pages 4 and 5, FIG. 1).

As an embodiment of a conventional method of manufacturing a semiconductor device, the following method of manufacturing a lateral PNP transistor has been known. In the lateral PNP transistor, after an insulating film having a thickness of 50 to 150 (μm) is formed on an N type silicon substrate, a known photolithography technology is used to form an opening in a region where an emitter diffusion layer and a collector diffusion layer are to be formed. By utilizing the opening, P type impurities, for example, ions of boron (B) are implanted to form the emitter diffusion layer and the collector diffusion layer. After an emitter draw-out electrode and a collector draw-out electrode are formed on the insulating film, another insulating film is formed. Thereafter, the known photolithography technology is used to form openings in the insulating film above the emitter draw-out electrode and the collector draw-out electrode, and thus an emitter electrode and a collector electrode are formed. This technology is described for instance in Japanese Patent Application Publication No. Hei 7 (1995)-283232 (Pages 6 and 7, FIGS. 1 to 4).

As described above, in the conventional semiconductor device, the emitter diffusion layer and the collector diffusion layer are formed in the epitaxial layer by use of an ion implantation method, for example. Moreover, a base width (Wb) between the emitter diffusion layer and the collector diffusion layer is reduced to the smallest near the surface of the epitaxial layer. By use of this structure, the free carriers (positive holes) injected into the base region from the emitter diffusion layer take a path near the surface of the epitaxial layer where the base width (Wb) is reduced to the smallest. Moreover, depending on an interfacial state such as a crystal defect formed on the surface of the epitaxial layer, most of the free carriers (positive holes) injected into the base region are caused to be recombined on the surface of the epitaxial layer. Thus, by disposing the collector diffusion layer so as to surround the emitter diffusion layer, a desired current capability is secured. The structure described above has a problem that a formation region of the collector diffusion layer is enlarged, and that it is difficult to reduce a device size.

Moreover, in the conventional method of manufacturing a semiconductor device, the ion implantation method is used once or a solid state diffusion method is used during formation of the emitter diffusion layer and the collector diffusion layer on the silicon substrate. Normally, in a case where the diffusion layer is formed by performing the ion implantation method once, the ion implantation method is performed under conditions that lead to a high concentration on the surface of the silicon substrate. Moreover, lateral diffusion is increased on the surface of the silicon substrate, and the base width (Wb) on the surface of the silicon substrate is reduced to the smallest. Moreover, the base width (Wb) on the surface of the silicon substrate is similarly reduced to the smallest also in a case of the solid state diffusion method. As a result, depending on the interfacial state such as a crystal defect formed on the surface of the epitaxial layer, most of the free carriers (positive holes) injected into the base region are recombined on the surface of the epitaxial layer. For this reason, by enlarging the formation region of the collector diffusion layer, the desired current capability is secured. The manufacturing method described above has a problem that the formation region of the collector diffusion layer is enlarged, and that it is difficult to reduce the device size.

Moreover, in the conventional method of manufacturing a semiconductor device, the insulating film on the base region is formed of an even and small thickness in order to prevent recombination of the free carriers (positive holes) on the surface of the silicon substrate. To this end, a two-layer structure of insulating films is adopted, and openings are formed in the respective insulating films. Accordingly, the emitter draw-out electrode and the emitter electrode are formed. Specifically, there is a problem that manufacturing steps become complicated, and that manufacturing costs are also increased.

Moreover, in the conventional method of manufacturing a semiconductor device, after the emitter diffusion layer and the collector diffusion layer of the lateral PNP transistor are formed on the silicon substrate, the insulating layer is formed on the silicon substrate. Subsequently, after contact holes are formed in the insulating layer by use of the known photolithography technology, the emitter electrode, the collector electrode and the like are formed. By use of the manufacturing method described above, a mask shift has to be considered with respect to the emitter diffusion layer and the collector diffusion layer during formation of the contact holes. As a result, there is a problem that a width of the contact hole is increased, and that it is difficult to reduce the device size.

### SUMMARY OF THE INVENTION

The present invention has been made in consideration for the foregoing circumstances. A semiconductor device of the present invention includes a semiconductor layer, and an emitter region, a base region and a collector region, which are formed in the semiconductor layer. The emitter region has a more widely diffused region in a deeper portion than in a vicinity of a surface of the semiconductor layer, and a distance between the emitter region and the collector region is reduced to the shortest in the widely diffused region of the emitter region. The collector region is disposed so as to form a square U-shape around the emitter region. Therefore, in the present invention, a smallest base width (Wb) is formed in a deep portion of the semiconductor layer. Moreover, immediately after the semiconductor device is turned on, free carriers (positive holes) take a path in the deep portion of the semiconductor layer. Thus, a desired hfe value can be obtained. By use of this structure, the collector region can be efficiently disposed, and a device size can be reduced.

Moreover, the semiconductor device of the present invention includes a concentration in the emitter region has two inflection regions along its concentration gradient. Therefore, in the present invention, a region with a high impurity concentration can be formed in a vicinity of a surface of the emitter region and in a deep portion thereof. By use of this structure, the smallest base width (Wb) is formed in the deep portion of the semiconductor layer. Moreover, a contact resistance of an emitter electrode can be reduced.

Moreover, in the semiconductor device of the present invention includes the semiconductor layer is obtained by stacking an epitaxial layer on a semiconductor substrate, and that the emitter region is formed only in the epitaxial layer. In the present invention, therefore, by forming the emitter region having a wide diffusion width in a deep portion of the epitaxial layer, the device size can be reduced.

A method of manufacturing a semiconductor device according to the present invention includes the steps of forming a square U-shaped collector region in a semiconductor layer, forming an insulating layer on an upper surface of the semiconductor layer, and thereafter forming a contact hole for an emitter region inside a region where the collector region is formed, and implanting ions of impurities for forming the emitter region through the contact hole by using the insulating layer as a mask. In the step of forming the emitter region, first and second diffusion layers having different impurity concentration peak positions are formed below the contact hole. Moreover, the ion implantation is performed so as to position the impurity concentration peak of the first diffusion layer deeper than the impurity concentration peak of the second diffusion layer. In the present invention, therefore, after the contact hole is formed, the emitter region is formed by utilizing the contact hole. By use of this manufacturing method, a device size is reduced without having to consider a mask shift during formation of the contact hole.

Moreover, the method of manufacturing a semiconductor device according to the present invention includes in the step of forming the emitter region, after the ion implantation for forming the second diffusion layer is performed, the ion implantation for forming the first diffusion layer is performed at an accelerating voltage higher than that used for the second diffusion layer. In the present invention, therefore, the emitter region is formed by utilizing the contact hole and performing ion implantation steps with different ion implantation conditions. By use of this manufacturing method, the emitter region having a large diffusion width in a portion deeper than in the vicinity of the surface thereof can be formed, and the smallest base width (Wb) can be formed in the deep portion of the semiconductor layer. Thus, it is possible to form the semiconductor device which obtains the desired hfe value.

### BRIEF DESCRIPTION OF THE DRAWINGS

FIG. 1A and FIG. 1B are respectively cross-sectional and plan views illustrating a semiconductor device according to a preferred embodiment of the present invention.

FIG. 2A is a cross-sectional view illustrating an emitter region and a collector region in the semiconductor device according to the preferred embodiment of the present invention, and FIG. 2B is a graph illustrating a concentration profile in the emitter region.

FIG. 3 is a graph illustrating a current amplification factor (hfe value) and a collector current (Ic) of each of semiconductor devices according to the preferred embodiment of the present invention and a conventional embodiment.

FIG. 4A and FIG. 4B are respectively cross-sectional and plan views illustrating the semiconductor device according to the conventional embodiment.

FIG. 5 is a cross-sectional view illustrating a method of manufacturing a semiconductor device according to the preferred embodiment of the present invention.

FIG. 6 is a cross-sectional view illustrating the method of manufacturing a semiconductor device according to the preferred embodiment of the present invention.

FIG. 7 is a cross-sectional view illustrating the method of manufacturing a semiconductor device according to the preferred embodiment of the present invention.

FIG. 8 is a cross-sectional view illustrating the method of manufacturing a semiconductor device according to the preferred embodiment of the present invention.

FIG. 9 is a cross-sectional view illustrating the method of manufacturing a semiconductor device according to the preferred embodiment of the present invention.

FIG. 10 is a cross-sectional view illustrating the method of manufacturing a semiconductor device according to the preferred embodiment of the present invention.

FIG. 11 is a cross-sectional view illustrating the method of manufacturing a semiconductor device according to the preferred embodiment of the present invention.

### DESCRIPTION OF THE PREFERRED EMBODIMENTS

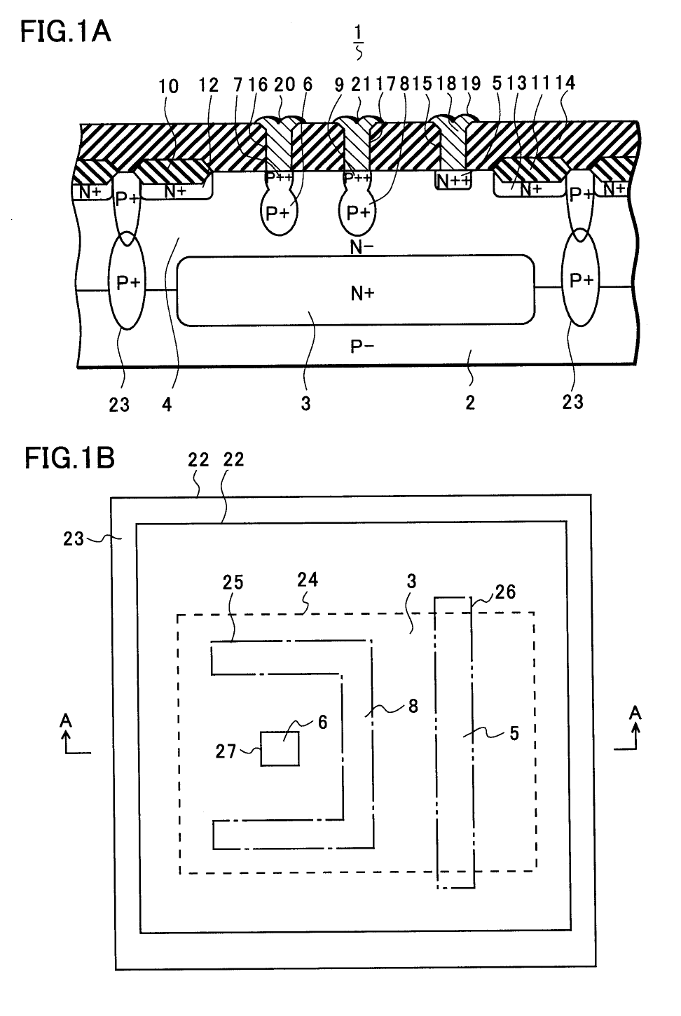

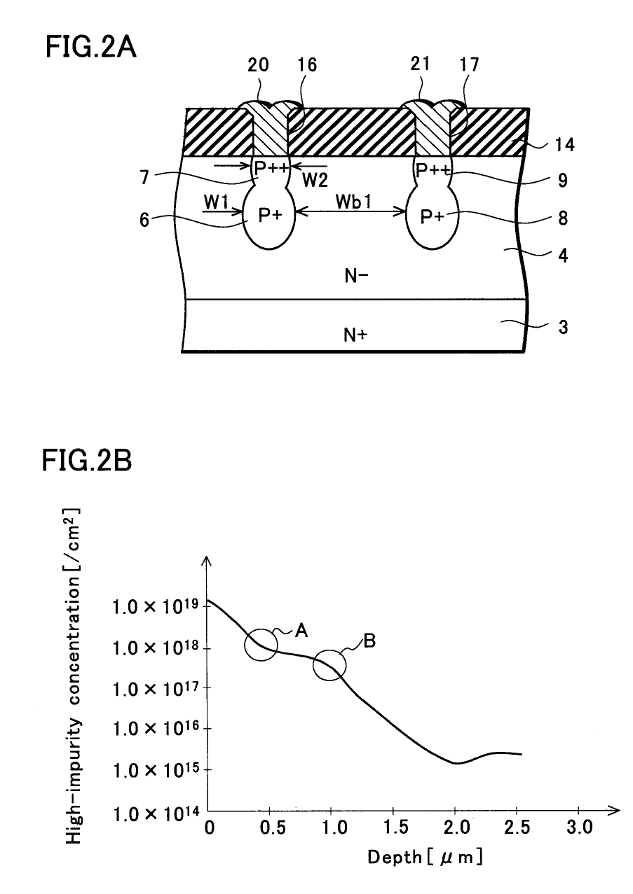

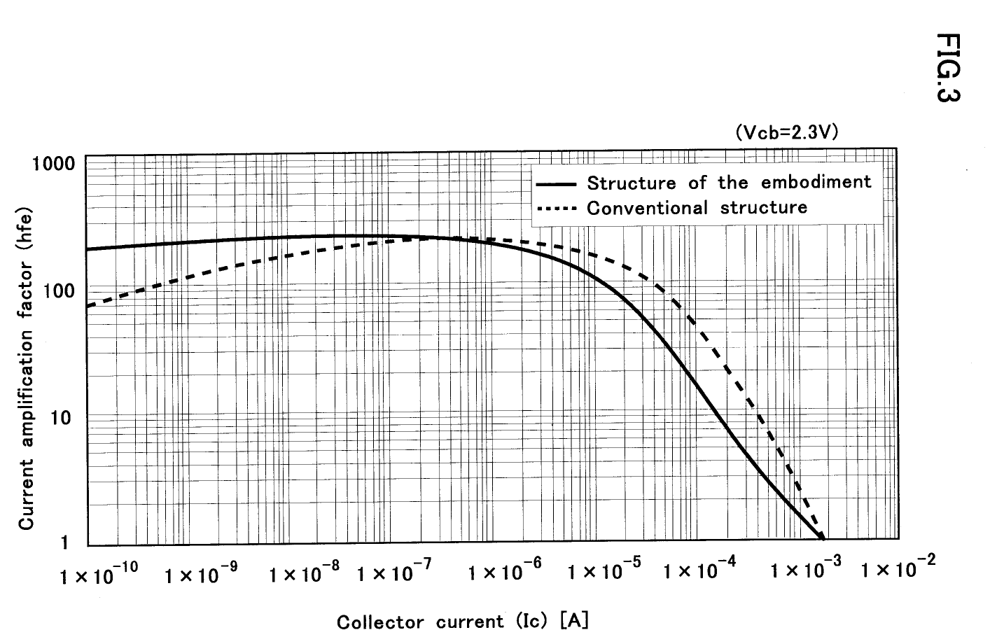

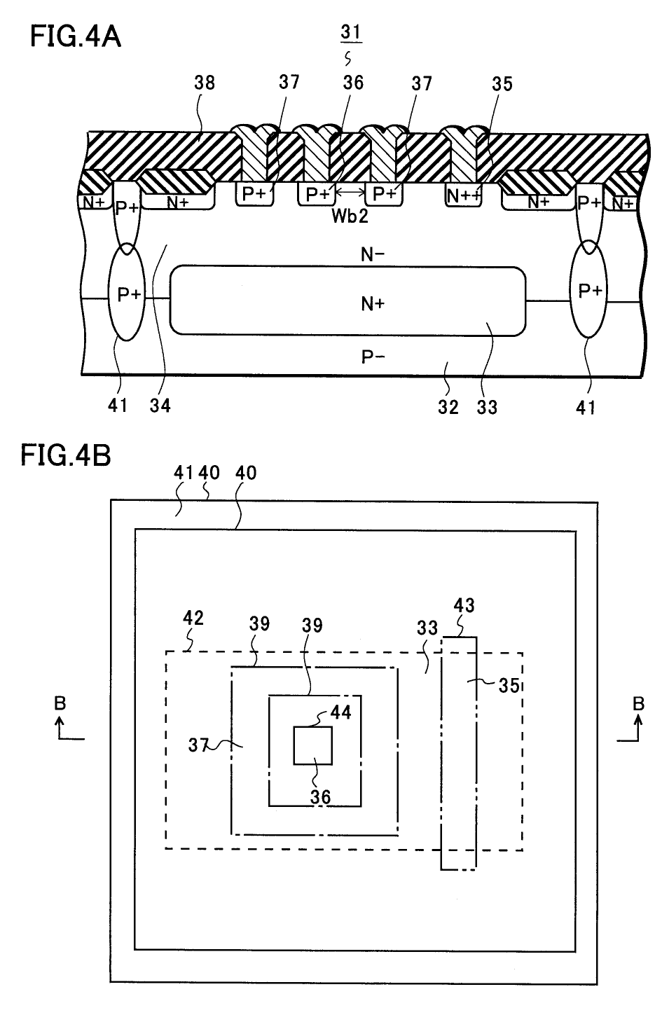

With reference to FIGS. 1 to 4, a semiconductor device according to a preferred embodiment of the present invention will be described in detail below. FIG. 1A is a cross-sectional view illustrating a semiconductor device according to the embodiment. FIG. 1B is a plan view illustrating the semiconductor device according to the embodiment. FIG. 2A is a cross-sectional view illustrating a collector region and an emitter region in the semiconductor device according to the embodiment. FIG. 2B is a graph illustrating a concentration profile in the collector region and the emitter region in the semiconductor device according to the embodiment. FIG. 3 is a graph illustrating a current amplification factor (hfe) and a collector current (Ic) of the semiconductor device according to the embodiment. FIG. 4A is a cross-sectional view of a conventional semiconductor device. FIG. 4B is a plan view illustrating the conventional semiconductor device.

As shown in FIG. 1A, a lateral PNP transistor 1 mainly is configured of a P type single crystal silicon substrate 2, an N type buried diffusion layer 3, an N type epitaxial layer 4, an N type diffusion layer 5 used as a base draw-out region, P type diffusion layers 6 and 7 used as an emitter region, and P type diffusion layers 8 and 9 used as a collector region.

The N type epitaxial layer 4 is formed on the P type single crystal silicon substrate 2. The N type buried diffusion layer 3 is formed in the substrate 2 and the epitaxial layer 4. Note that although a case where one epitaxial layer 4 is formed on the substrate 2 is shown in this embodiment, the preferred embodiment of the present invention is not limited to this case. For example, the preferred embodiment of the present invention may be only the substrate or a plurality of epitaxial layers stacked on an upper surface of the substrate. Moreover, the substrate may be an N type single crystal silicon substrate or a compound semiconductor substrate.

The N type diffusion layer 5 is formed in the epitaxial layer 4. The N type epitaxial layer 4 is used as a base region, and the N type diffusion layer 5 is used as the base draw-out region.

The P type diffusion layers 6 and 7 are formed in the epitaxial layer 4. In the P type diffusion layer 6, the P type diffusion layer 7 is formed so as to have a formation region thereof overlap with that of the diffusion layer 6. The P type diffusion layers 6 and 7 are used as the emitter region. Note that, as shown in FIG. 1A, the P type diffusion layer 7 is formed so as to overlap with the P type diffusion layer 6, and thus the emitter region is formed in the shape of a potbelly.

The P type diffusion layers 8 and 9 are formed in the epitaxial layer 4. In the P type diffusion layer 8, the P type diffusion layer 9 is formed so as to have a formation region thereof overlap with that of the diffusion layer 8. The P type diffusion layers 8 and 9 are used as the collector region. Note that, as shown in FIG. 1A, the P type diffusion layer 9 is formed so as to overlap with the P type diffusion layer 8, and thus the collector region is formed in the shape of a potbelly.

LOCOS (Local Oxidation of Silicon) oxide films 10 and 11 are formed in the epitaxial layer 4. Each of the LOCOS oxide films 10 and 11 has a thickness of, for example, about 3000 to 10000 (Å) in its flat portion. Below the LOCOS oxide films 10 and 11, N type diffusion layers 12 and 13 are formed. The N type diffusion layers 12 and 13 prevent an inversion of a surface of the epitaxial layer 4.

An insulating layer 14 is formed on an upper surface of the epitaxial layer 4. The insulating layer 14 is formed of an NSG (Nondoped Silicate Glass) film, a BPSG (Boron Phospho Silicate Glass) film or the like. By use of a known photolithography technology, contact holes 15, 16 and 17 are formed in the insulating layer 14 by dry etching using, for example, CHF₃ or CF₄ gas.

In the contact holes 15, 16 and 17, aluminum alloy films 18 made of, for example, an Al—Si film, an Al—Si—Cu film, an Al—Cu film or the like are selectively formed. Thus, a base electrode 19, an emitter electrode 20 and a collector electrode 21 are formed.

As shown in FIG. 1B, a region surrounded by solid lines 22 indicates a isolation region 23, and a region surrounded by dotted lines 24 indicates the N type buried diffusion layer 3. Moreover, a region surrounded by chain dashed lines 25 indicates the P type diffusion layer 8, a region surrounded by chain double dashed lines 26 indicates the N type diffusion layer 5, and a region surrounded by solid lines 27 indicates the P type diffusion layer 6. As shown in FIG. 1B, the P type diffusion layer 8 that is the collector region is disposed so as to form a square U shape around the P type diffusion layer 6 that is the emitter region. The cross-sectional view shown in FIG. 1A is a cross-sectional view taken along the line A-A shown in FIG. 1B, which includes the P type diffusion layer 6 that is the emitter region.

As shown in FIG. 2A, the emitter region is formed of the P type diffusion layers 6 and 7. Although described in detail later in a method of manufacturing a semiconductor device, the P type diffusion layers 6 and 7 are formed by two ion implantation steps having different conditions after the contact hole 16 is formed. The P type diffusion layer 6 is formed under conditions that allow ions of impurities to be implanted into a deep portion of the epitaxial layer 4, compared with the P type diffusion layer 7. Thus, a width W1 (a region having a largest diffusion width) of the P type diffusion layer 6 and a width W2 (a region having a largest diffusion width) of the P type diffusion layer 7 are set in a relationship of W1>W2. Moreover, a width Wb1 of the base region positioned between the emitter region and the collector region is set to be the smallest in the region of the width W1 of the P type diffusion layer 6.

Moreover, as shown in FIG. 2B, the emitter region has two inflection regions in its concentration profile as indicated by circles A and B. This concentration profile is realized by implanting and diffusing the impurities so as to allow an impurity concentration peak of the P type diffusion layer 6 to exist deeper than an impurity concentration peak of the P type diffusion layer 7. By use of this manufacturing method, a contact resistance can be reduced by increasing the impurity concentration in a vicinity of a surface of the emitter region. Meanwhile, in a deep portion of the emitter region, as described above, a region where the base region width Wb1 is set to be the smallest can be formed.

By use of the structure described above, immediately after the lateral PNP transistor 1 is turned on, a current takes a path in the deep portion of the epitaxial layer 4, where the base region width Wb1 is set to be the smallest. Since free carriers (positive holes) injected into the base region take a path in the deep portion of the epitaxial layer 4, an amount of the carriers to be recombined can be significantly reduced. Specifically, the deep portion of the epitaxial layer 4 is less likely to be affected by an interfacial state between the silicon and the silicon oxide film, such as a crystal defect formed on the surface of the epitaxial layer 4. As a result, as shown in FIG. 3, an hfe value can be improved by reduction in recombination of the free carriers (positive holes) even in a minute current region immediately after the ON operation.

Note that, as shown in FIGS. 2A and 2B, the collector region formed of the P type diffusion layers 8 and 9 is also formed by using the contact hole 17 and also has two inflection regions in its concentration profile, as in the case of the emitter region described above. Moreover, at least the emitter region may be formed to have the above-described shape, and the collector region may be formed before the contact hole 17 is formed

As shown in FIG. 4A, a conventional lateral PNP transistor 31 according to one embodiment mainly is configured of a P type single crystal silicon substrate 32, an N type buried diffusion layer 33, an N type epitaxial layer 34, an N type diffusion layer 35 used as a base draw-out region, a P type diffusion layer 36 used as an emitter region, and a P type diffusion layer 37 used as a collector region.

The N type epitaxial layer 34 is formed on the P type single crystal silicon substrate 32. The N type buried diffusion layer 33 is formed in the substrate 32 and the epitaxial layer 34. In the epitaxial layer 34, the N type diffusion layer 35 and the P type diffusion layers 36 and 37 are formed, for example, by using a photoresist as a mask. Specifically, in the conventional lateral PNP transistor 31, the P type diffusion layers 36 and 37, which form the emitter region and the collector region, have the largest diffusion width in a vicinity of a surface of the epitaxial layer 34. Moreover, a base width Wb2 between the emitter region and the collector region is set to be the smallest in the vicinity of the surface of the epitaxial layer 34.

Moreover, as shown in FIG. 4B, in the conventional lateral PNP transistor 31, the collector region is disposed in a ring shape so as to surround the emitter region, as indicated by chain dashed lines 39. Note that a region surrounded by solid lines 40 indicates a isolationregion 41, a region surrounded by dotted lines 42 indicates the N type buried diffusion layer 33, a region surrounded by chain double dashed lines 43 indicates the N type diffusion layer 35, and a region surrounded by solid lines 44 indicates the P type diffusion layer 36.

In the lateral PNP transistor 1 of this embodiment, as shown in FIG. 1B, the P type diffusion layer 8 that is the collector region is disposed so as to form a square U shape around the P type diffusion layer 6 that is the emitter region. Specifically, compared with the conventional lateral PNP transistor 31, the collector region can be reduced, and a device size can be reduced by about 30 (%). Meanwhile, even though the collector region is reduced, as shown in FIG. 3, a current capability can be maintained compared with the conventional lateral PNP transistor 31. This is because, although the lateral PNP transistor 1 is operated by the entire emitter region, the shape of the P type diffusion layers 6 and 7 increases a surface area of the emitter region to improve a current amount. Specifically, it is possible to realize the lateral PNP transistor 1 which can reduce the device size while maintaining the current capability.

Note that, in this embodiment, as shown in FIG. 1B, the description has been given of the case where the P type diffusion layers 8 and 9, which form the square U-shaped collector region, have an opening on the isolationregion 23 side. However, the preferred embodiment of the present invention is not limited to the above case. For example, since the P type diffusion layers 8 and 9 are formed in the square U shape, an effect of reducing the device size can be obtained even in a case where the opening is provided in an arbitrary direction. Particularly, in a case where the N type diffusion layer 5, which forms the base region, has an opening, the collector region is prevented from becoming a barrier between the base and the emitter. Thus, a base resistance value can be further reduced, and current characteristics can be improved. Besides, various changes can be made without departing from the scope of the preferred embodiment of the present invention.

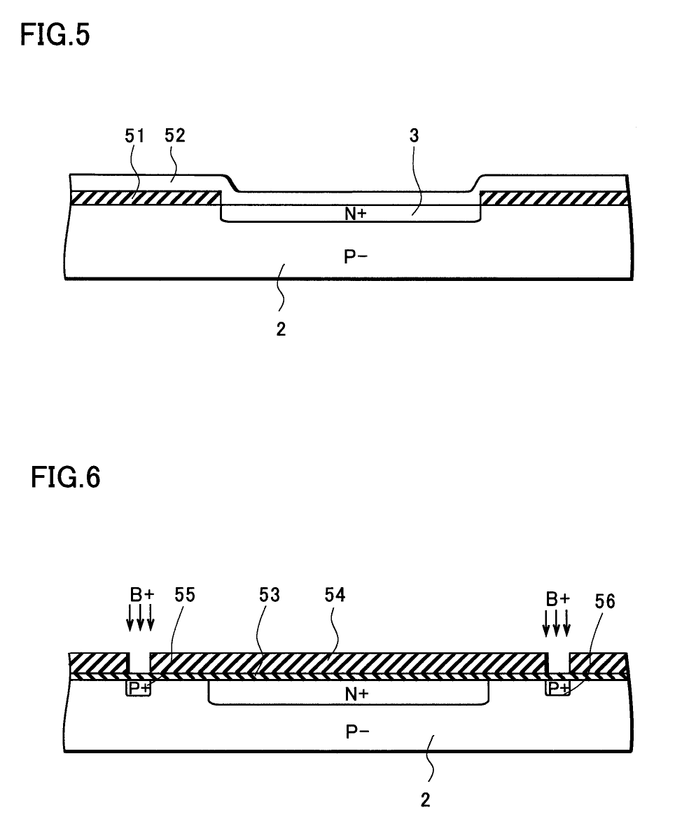

Next, with reference to FIGS. 5 to 11, detailed description will be given of a method of manufacturing a semiconductor device according to a preferred embodiment of the present invention. FIGS. 5 to 11 are cross-sectional views illustrating the method of manufacturing a semiconductor device according to this embodiment. Note that the following description is given of a case where, for example, a lateral PNP transistor is formed in one of element formation regions divided by a isolationregion. However, the preferred embodiment of the present invention is not limited to this case. For example, an N channel MOS transistor, a P channel MOS transistor, an NPN transistor, a vertical PNP transistor and the like may be formed in the other element formation regions to form a semiconductor integrated circuit device.

First, as shown in FIG. 5, a P type single crystal silicon substrate 2 is prepared. A silicon oxide film 51 is formed on the substrate 2, and the silicon oxide film 51 is selectively removed so as to form an opening on a formation region of an N type buried diffusion layer 3. Thereafter, by using the silicon oxide film 51 as a mask, a liquid source 52 containing N type impurities, for example, antimony (Sb) is applied onto a surface of the substrate 2 by use of a spin-coating method. Subsequently, after the antimony (Sb) is thermally diffused to form the N type buried diffusion layer 3, the silicon oxide film 51 and the liquid source 52 are removed.

Next, as shown in FIG. 6, a silicon oxide film 53 is formed on the substrate 2, and a photoresist 54 is formed on the silicon oxide film 53. Thereafter, by use of a known photolithography technology, openings are formed in the photoresist 54 on regions where P type buried diffusion layers 55 and 56 are formed. Subsequently, ions of P type impurities, for example, boron (B) are implanted from the surface of the substrate 2 at an accelerating voltage of 180 to 200 (keV) and a dose of 1.0×10¹² to 1.0×10¹⁴ (/cm²).

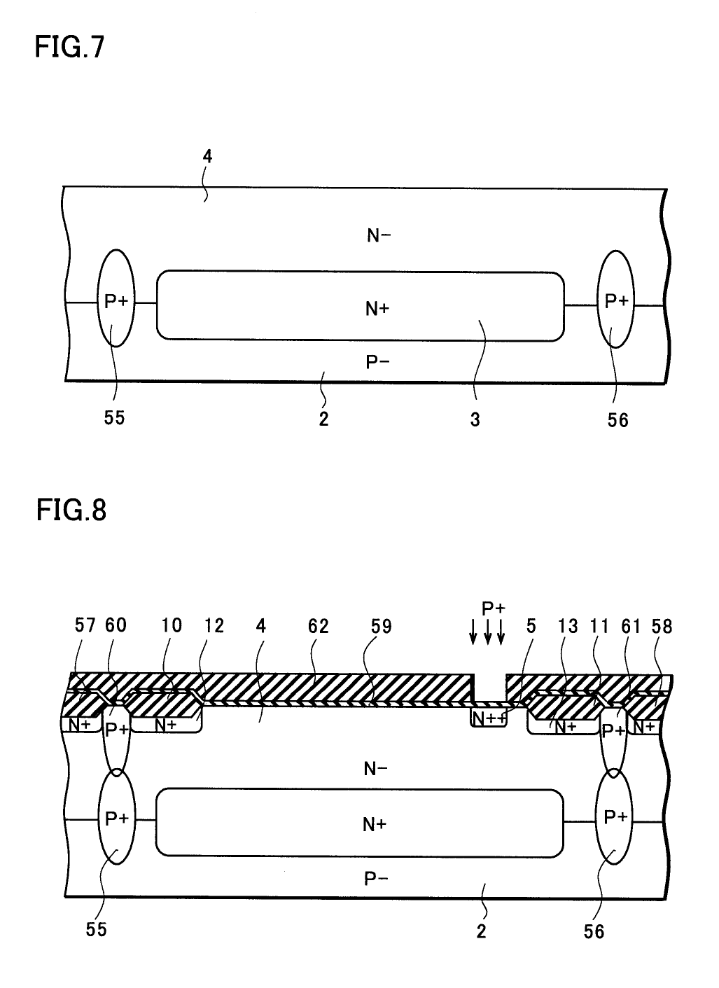

Next, as shown in FIG. 7, the substrate 2 is placed on a susceptor of a vapor phase epitaxial growth apparatus. Thereafter, the substrate 2 is exposed to a high temperature, for example, about 1200 (° C.) by lamp heating, and SiHCl₃ gas and H₂ gas are introduced into a reaction tube. By this step, an epitaxial layer 4 having a specific resistance of 0.1 to 10.0 (Ω·cm) and a thickness of about 1.0 to 10.0 (μm), for example, is grown on the substrate 2. By a heat treatment in the above step of forming the epitaxial layer 4, the P type buried diffusion layers 55 and 56 and the N type buried diffusion layer 3 are thermally diffused.

Next, as shown in FIG. 8, LOCOS oxide films 10, 11, 57 and 58 are formed in desired regions of the epitaxial layer 4. In this event, by utilizing a mask for forming the LOCOS oxide films 10 and 11, N type diffusion layers 12 and 13 are formed. By use of this manufacturing method, the N type diffusion layers 12 and 13 can be formed with good positional accuracy with respect to the LOCOS oxide films 10 and 11. Next, a silicon oxide film 59 is formed on the epitaxial layer 4. Thereafter, a photoresist (not shown) is formed on the silicon oxide film 59, and openings are formed in the photoresist on regions where P type diffusion layers 60 and 61 are to be formed. Subsequently, ions of P type impurities, for example, boron (B) are implanted from the surface of the epitaxial layer 4 at an accelerating voltage of 150 to 170 (keV) and a dose of 1.0×10¹² to 1.0×10^{14 (/cm}²). Thus, the P type diffusion layers 60 and 61 are formed.

Thereafter, a photoresist 62 is formed again on the silicon oxide film 59, and an opening is formed in the photoresist 62 on a region where an N type diffusion layer 5 is to be formed. Subsequently, ions of N type impurities, for example, phosphorus (P) are implanted from the surface of the epitaxial layer 4 to form the N type diffusion layer 5.

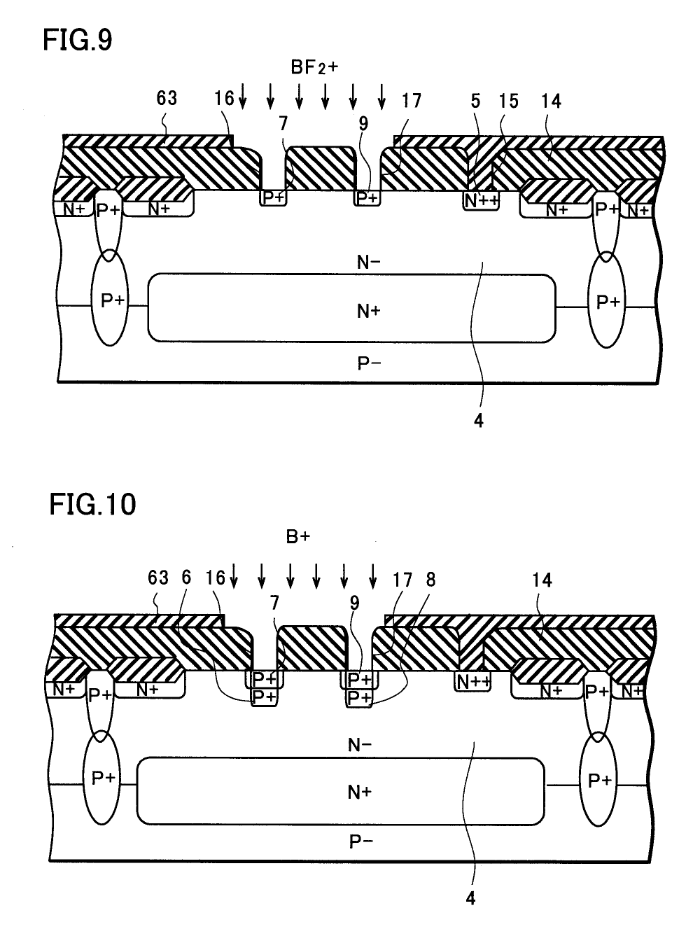

Next, as shown in FIG. 9, on the epitaxial layer 4, an NSG film, a BPSG film or the like is deposited, for example, as an insulating layer 14. Thereafter, by use of the known photolithography technology, contact holes 15, 16 and 17 are formed in the insulating layer 14 by dry etching using, for example, CHF₃ or CF₄ gas.

A photoresist 63 is formed on the insulating layer 14, and the photoresist 63 is selectively removed so as to set the contact holes 16 and 17 in an opened state. Subsequently, ions of P type impurities, for example, boron fluoride (BF) are implanted into the epitaxial layer 4 through the contact holes 16 and 17 at an accelerating voltage of 40 to 60 (keV) and a dose of 1.0×10¹⁴ to 1.0×10¹⁶ (/cm²). Thus, below the contact holes 16 and 17, P type diffusion layers 7 and 9 are formed so as to correspond to the shapes of the openings of the contact holes 16 and 17.

Next, as shown in FIG. 10, by using the photoresist 63, while the contact holes 16 and 17 are in the opened state, ions of P type impurities, for example, boron (B) are implanted into the epitaxial layer 4 through the contact holes 16 and 17 at an accelerating voltage of 120 to 160 (keV) and a dose of 1.0×10¹³ to 1.0×10¹⁵ (/cm²). Thus, below the contact holes 16 and 17, P type diffusion layers 6 and 8 are formed so as to correspond to the shapes of the openings of the contact holes 16 and 17.

In this embodiment, by utilizing the contact holes 16 and 17, the P type diffusion layers 6 and 7 used as the emitter region and the P type diffusion layers 8 and 9 used as the collector region are formed by performing two ion implantation steps. As described above, in the second ion implantation, ions of the impurities are implanted at the accelerating voltage higher than that in the first ion implantation. By use of this manufacturing method, a region having the smallest base width Wb1 (see FIG. 2A) is formed in the deep portion of the epitaxial layer 4.

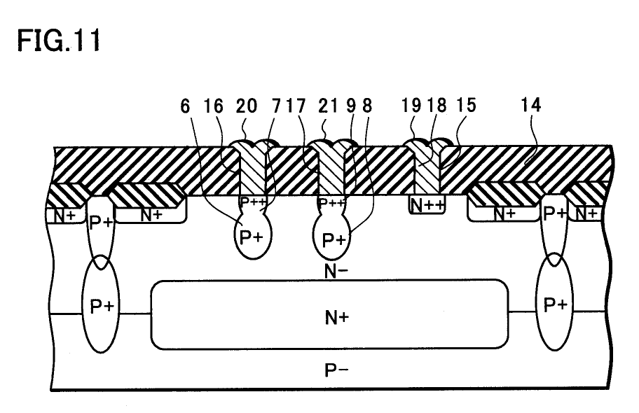

Moreover, by performing the two ion implantation steps, the P type diffusion layers 6 and 7 as well as the P type diffusion layers 8 and 9 can be formed so as to correspond to the formation positions of the contact holes 16 and 17. Thus, a mask shift between the P type diffusion layers 6 and 7 and the contact hole 16 does not have to be considered. Similarly, a mask shift between the P type diffusion layers 8 and 9 and the contact hole 17 does not have to be considered. For example, in a case where the contact hole 16 is formed after the P type diffusion layers 6 and 7 are formed, an extra opening region of about 0.6 (μm) is required, as a mask shift width, around the contact hole 16 in addition to a normally required width of the contact hole 16. However, in this embodiment, since the mask shift width does not have to be considered, an extra mask shift width (1.2 (μm)), which is considered on both sides of the contact hole 16, can be omitted in the cross-sectional view shown in FIG. 11. Accordingly, by reducing the width of the contact hole 16, the size of the lateral PNP transistor can be reduced. Note that the same effect can be obtained also for the contact hole 17.

Lastly, as shown in FIG. 11, in the contact holes 15, 16 and 17, aluminum alloy films 18 made of, for example, an Al—Si film, an Al—Si—Cu film, an Al—Cu film or the like are selectively formed. Thus, a base electrode 19, an emitter electrode 20 and a collector electrode 21 are formed.

Note that, in this embodiment, the description has been given of the case where the P type diffusion layers 6 and 7 used as the emitter region and the P type diffusion layers 8 and 9 used as the collector region are formed by performing the two ion implantation steps using different accelerating voltages through the contact holes 16 and 17. However, the preferred embodiment of the present invention is not limited to this case. For example, the P type diffusion layers 6 and 7 and the P type diffusion layers 8 and 9 may be formed by performing a plurality of ion implantation steps, such as three times and four times, through the contact holes 16 and 17. Moreover, the effect described above can be obtained also in a case where the contact hole 16 is used only during formation of the P type diffusion layers 6 and 7 used at least as the emitter region. Besides, various changes can be made without departing from the scope of the preferred embodiment of the present invention.

In the preferred embodiment of the present invention, the emitter region is formed up to the deep portion of the epitaxial layer. By use of this structure, even in a case where the collector region is reduced and the device size is reduced, a current capability can be maintained.

Moreover, in the preferred embodiment of the present invention, the emitter region has a region having a larger diffusion width in the deeper portion than in the surface region thereof. By use of this structure, the smallest base width (Wb) is formed in the deep portion of the epitaxial layer, and recombination of the free carriers (positive holes) is prevented. Thus, the desired hfe value can be obtained.

Moreover, in the preferred embodiment of the present invention, the emitter region has the region having the high impurity concentration in the vicinity of the surface thereof and in the deep portion. By use of this structure, the contact resistance of the emitter electrode can be reduced.

Moreover, in the preferred embodiment of the present invention, after the insulating layer is deposited on the epitaxial layer and the contact hole is formed in the insulating layer, the emitter region is formed by utilizing the contact hole. By use of this manufacturing method, the device size can be reduced without having to consider the mask shift between the contact hole and the diffusion layers for the emitter region and for the collector region.

Moreover, in the preferred embodiment of the present invention, the emitter region is formed by performing the ion implantation steps with the different ion implantation conditions. By use of this manufacturing method, the smallest base width (Wb) is formed in the deep portion of the epitaxial layer. Thus, the desired hfe value can be obtained. Moreover, the contact resistance can be reduced by increasing the impurity concentration in the vicinity of the surface of the emitter region.

What is claimed is:

1. A semiconductor device comprising:
a semiconductor layer; and
an emitter region, a base region and a collector region, which are formed in the semiconductor layer,
wherein the emitter region has a more widely diffused region in a deeper portion than in a vicinity of a surface of the semiconductor layer, and a distance between the emitter region and the collector region is reduced to the shortest in the widely diffused region of the emitter region, and
wherein the collector region is disposed so as to form a square U-shape around the emitter region.

2. The semiconductor device according to claim 1, wherein a concentration in the emitter region has two inflection regions along its concentration gradient.

3. The semiconductor device according to claim 1, wherein the semiconductor layer is obtained by stacking an epitaxial layer on a semiconductor substrate, and the emitter region is formed only in the epitaxial layer.

4. A method of manufacturing a semiconductor device, comprising the steps of:
forming a square U-shaped collector region in a semiconductor layer, forming an insulating layer on an upper surface of the semiconductor layer, and thereafter forming a contact hole for an emitter region inside a region where the collector region is formed; and
implanting ions of impurities for forming the emitter region through the contact hole by using the insulating layer as a mask,
wherein, in the step of forming the emitter region, first and second diffusion layers having different impurity concentration peak positions are formed below the contact hole, and the ion implantation is performed so as to position the impurity concentration peak of the first diffusion layer deeper than the impurity concentration peak of the second diffusion layer.

5. The method of manufacturing a semiconductor device according to claim 4, wherein, in the step of forming the emitter region, after the ion implantation for forming the second diffusion layer is performed, the ion implantation for forming the first diffusion layer is performed at an accelerating voltage higher than that used for forming the second diffusion layer.
